(19) United States
(12) Patent Application Publication
(10) Pub. No.: US 2010/0141248 A1
(43) Pub. Date: Jun. 10, 2010

(54) Magnetostriction Apparatus

(76) Inventor: Motoaki Suzukawa, Tokyo (JP)

Correspondence Address: CARR & FERRELL LLP, 2200 GENG ROAD, PALO ALTO, CA, 94303, US

(21) Appl. No.: 12/095,740

(22) PCT Filed: Sep. 1, 2006
(86) PCT No.: PCT/JP2006/317373

§ 371 Date: Oct. 13, 2009

(30) Foreign Application Priority Data
Dec. 22, 2005 (JP) 2005-370919

(51) Int. Cl. G01R 33/02; H01H 55/00

(52) U.S. Cl. 324/244; 335/215

(57) ABSTRACT

An electronic device is provided with a magnetostriction apparatus and a main body. The magnetostriction apparatus includes a super magnetostrictor which extracts and contracts in accordance with a magnetic field, a coil and bias magnets which generate the magnetic field, and a housing which maintains the components at predetermined positions. The magnetostriction apparatus is fitted to the main body such that the super magnetostrictor is perpendicular to the face of the main body where the apparatus is fitted. The housing is connected to the main body so that a predetermined pressure is applied to the super magnetostrictor by the main body and the housing.

### CROSS-REFERENCE TO RELATED APPLICATION

The present application is the national phase under 35 U.S.C. §371 of Patent Cooperation Treaty application number PCT/JP2006/317373 filed Sep. 1, 2006, which claims the priority benefit of Japanese patent application number 2005-370919 filed Dec. 22, 2005. The disclosure of each of the aforementioned applications is incorporated herein by reference.

### BACKGROUND OF THE INVENTION

1. Field of the Invention

The present invention relates to a magnetostriction apparatus for generating or detecting vibration by using a magnetostrictor.

2. Description of Related Art

Some magnetic materials undergo strain in accordance with variations in a magnetic field outside the materials. Stressing and deforming such a magnetic material changes the magnetic characteristic of the material according to the stress. This phenomenon is called magnetostriction. Materials that exhibit displacement 50 to 100 times greater than that of previously known magnetostrictors have recently been discovered. Such materials are called super magnetostrictors.

By applying an alternate magnetic field to a magnetostrictor, vibration at the same frequency as that of the alternating magnetic field can be generated. A magnetostrictor-based vibration generator provided in a headphone or a hearing aid should be small and lightweight. Japanese patent publication number JP 2001-258095 proposes a technology for reducing the size and weight of a vibration generator by applying prestress to a super magnetostrictor so as to improve transducing efficiency and by omitting a vibration plate so as to conduct the vibration by the super magnetostrictor directly to a target object.

The present application improves upon the prior art through further reduction in the size and weight of a vibration generator while maintaining the excellent characteristics of a super magnetostrictor.

### SUMMARY OF THE INVENTION

Embodiments of the present invention provide for a small and lightweight magnetostriction apparatus.

In one embodiment, a magnetostriction apparatus includes a magnetostrictor, which expands and contracts in accordance with a magnetic field; a magnetic field generating means that generates the magnetic field; and a housing that holds the magnetostrictor and the magnetic field generating means at predetermined positions, wherein the housing is connected to an external member so that a predetermined pressure is applied to the magnetostrictor by the external member and the housing. The external member may include a circuit that supplies a signal for generating the magnetic field to the magnetic field generating means. The housing may include a yoke, which adjusts a magnetic circuit of the magnetic field generated by the magnetic field generating means.

A further embodiment of the present invention relates to a magnetostriction apparatus that includes a magnetostrictor, the magnetic characteristic of which varies in accordance with variation applied from outside. The apparatus further includes detecting means that detect variations in the magnetic characteristic in the form of an electrical signal and a housing that holds the magnetostrictor and the detecting means at predetermined positions, wherein the housing is connected to an external member so as that a predetermined pressure is applied to the magnetostrictor by the external member and the housing. The external member may include a circuit that acquires the electrical signal from the detecting means.

The magnetostriction apparatus may exclude a structure that supports an end of the magnetostrictor opposite to an end supported by the housing and applies a predetermined pressure to the magnetostrictor. By omitting a prestress cap provided in a related-art magnetostriction apparatus and causing the external member to function as a prestress cap, the weight of the magnetostriction apparatus may be reduced and the size in the height direction can be significantly reduced. Another advantage is that the external member to which the magnetostriction apparatus is fitted may be more flexibly designed than in the related art.

The housing may include a yoke for creating a closed magnetic path within the housing. The face of the housing where the magnetostriction apparatus is connected to the external member may be open and the magnetostriction apparatus may be connected to the external member such that the end of the magnetostrictor facing the external member or a constituting member provided in the magnetostrictor to face the external member comes into contact with the external member. The magnetostriction apparatus may further include a vibrating unit that conducts vibration at an end of the magnetostrictor opposite to an end facing the external member outside the magnetostriction apparatus.

### BRIEF DESCRIPTION OF THE DRAWINGS

FIG. 1 illustrates a magnetostriction apparatus as found in the prior art.

FIG. 2 is a table showing the characteristics of a super magnetostrictive material and a piezoelectric material.

FIG. 3A schematically illustrates the vibration of a magnetostrictor.

FIG. 3B is further schematic illustration of the vibration of a magnetostrictor.

FIG. 4 illustrates an embodiment of the presently disclosed magnetostriction apparatus.

FIG. 5 illustrates a headphone including the magnetostriction apparatus of FIG. 4.

FIG. 6 illustrates a magnetostriction apparatus in accordance with an embodiment of the presently disclosed invention.

FIG. 7 illustrates an electronic device according to the embodiment disclosed in FIG. 6.

FIG. 8 illustrates headphones including the magnetostriction apparatus of FIGS. 6 and 7.

FIG. 9 illustrates an electronic device encompassing an alternative embodiment of the presently disclosed invention.

### DETAILED DESCRIPTION

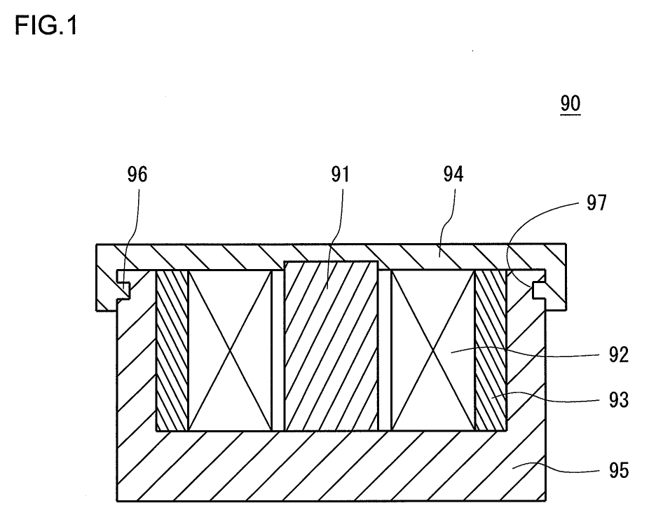

FIG. 1 illustrates a magnetostriction apparatus as found in the prior art. Magnetostriction apparatus 90 includes magnetostrictor 91, coil 92, bias magnet 93, cap 94, and case 95. The magnetostrictor 91 has a substantially cylindrical shape and expands and contracts in the direction of height in accordance with a magnetic field generated by the coil 92 and the bias magnet 93. The magnetostrictor 91 is provided substantially at the center of the case 95 so that the height thereof is aligned with the depth of the substantially cylindrical case 95. The coil 92 is provided around the magnetostrictor 91.

An electric current supplied from an external drive generates a magnetic field around the magnetostrictor 91. The bias magnet 93 provides a bias magnetic field of a predetermined intensity around the magnetostrictor 91 on a permanent basis. The cap 94 is substantially disk-shaped and is provided to seal the case 95, which contains the magnetostrictor 91, the coil 92, and the bias magnet 93 inside. An engagement groove 96 is formed toward the top of the side wall of the case 95. A latch part 97 of the cap 94 is latched by the engagement groove 96 so as to secure the cap 94 and the case 95 to each other. The magnetostrictor 91 is pressed from above and from below by the cap 94 and the case 95, respectively, so as to undergoes certain prestress.

As an alternating current is supplied to the coil 92, an alternating magnetic field is generated around the coil 92 causing the magnetostrictor 91 to expand and contract in the axis direction. The cap 94 vibrates as a result of the expansion and contraction of the magnetostrictor 91 and the vibration is conducted outside via the cap 94. If the magnetostriction apparatus 90 shown in FIG. 1 is used in a headphone, the cap 94 is pressed against the neighborhood of the ear so as to conduct the vibration generated by the magnetostrictor 91 to the head via the cap 94. The cap 94 is formed so as to have larger elasticity than the bottom of the case 95. This prevents the vibration of the magnetostrictor 91 from being absorbed by the bottom of the case 95 and ensures that the vibration is efficiently conducted to a target object (e.g., the head of the user) via the cap 94.

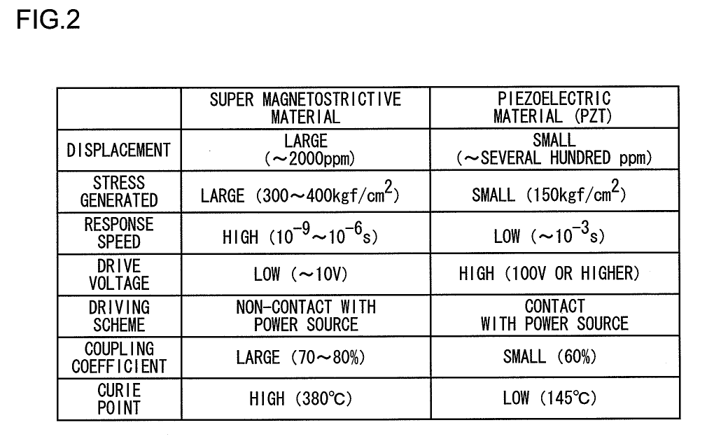

FIG. 2 is a table showing the characteristics of a super magnetostrictive material and a piezoelectric material. A super magnetostrictive material such as terbium-dysprosium-iron (TbDyFe) has superior characteristics than a piezoelectric material such as lead zirconate titanate (PZT: PbZrO3-PbTiO3) as described below. A super magnetostrictive material is characterized by larger stress developed therein and relatively large displacement. Accordingly, vibration generated in a super magnetostrictor can be efficiently conducted outside. Further, since the drive voltage is lower, the power consumption is smaller. Moreover, since the Curie point is higher, use in a higher temperature is possible. Since the super magnetostrictor vibrates in the presence of a magnetic field, the driven part is not in contact with a power supply. As such, the material is highly safe to use.

Moreover, a super magnetostrictive material is characterized by large stress developed therein and so can properly conduct low-frequency, high-energy vibration outside. An additional benefit of high response speed enables the material to properly follow a high-frequency input signal to generate vibration. Thus, a flat characteristic is achieved over a wide frequency range. This is particularly advantageous in a headphone or a speaker in which the material is used. A related-art headphone using a piezoelectric material can only generate sound up to about 5-20 kHz. By using a super magnetostrictive material, sound at 50 kHz or higher can be generated. The present headphone and speaker using a super magnetostrictive material is capable of reproducing sound in an ultrasonic range with a high fidelity, instead of using a piezoelectric material not capable of generating high-frequency sound.

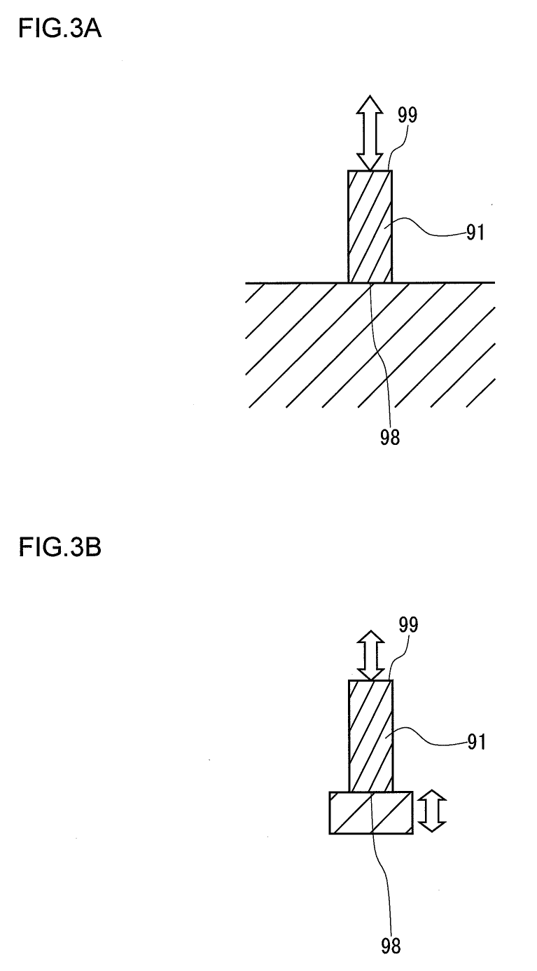

FIGS. 3A and 3B each schematically illustrate the vibration of a magnetostrictor. As shown in FIG. 3A, if one end 98 of the magnetostrictor 91 is fixed (the fixed end), the magnetostrictor 91 expands and contracts only toward or away from the other end (the output end). Therefore, vibration occurring when the magnetostrictor 91 expands or contracts is efficiently conducted outside via the output end 99. If the fixed end 98 vibrates due to the fact that the member supporting the fixed end 98 of the magnetostrictor 91 is elastic or lightweight as shown in FIG. 3B, displacement of vibration or stress occurring conducted from the output end 99 outside is attenuated accordingly.

As the cap 94 of the magnetostriction apparatus 90 shown in FIG. 1 is pressed against the target object to conduct the vibration of the magnetostrictor 91 to the target object, a force is generated whereby the fixed end 98 of the magnetostrictor 91 presses the bottom of the case 95 due to reaction to the force with which the cap 94 presses the target object. If the case 95 does not have enough inertial mass as shown in FIG. 3B, vibration at the output end 99 is attenuated, preventing vibration of the magnetostrictor 91 from being properly conducted to the target object. The phenomenon will be particularly noticeable in a low-frequency range characterized by high vibration energy, with the result that, for example, bass sound is difficult to hear with a headphone which uses the magnetostriction apparatus 90.

The member in contact with the fixed end 98 of the magnetostrictor 91 (e.g., the case 95 of the magnetostriction apparatus 90 of FIG. 1) must have enough inertial mass and hardness in order to prohibit degradation in the frequency characteristic of the magnetostrictor 91 over a wide frequency range. It will be noted that the challenge is quite unique to a magnetostrictor, which is characterized by greater stress developed therein than in a piezoelectric device. An inertial mass 13.8 times or larger; 21 times or larger; or—preferably—69 times or larger than the moving mass should be provided at the fixed end 98 of the magnetostrictor 91 to efficiently drive a super magnetostriction apparatus as a vibration generator over a wide frequency range.

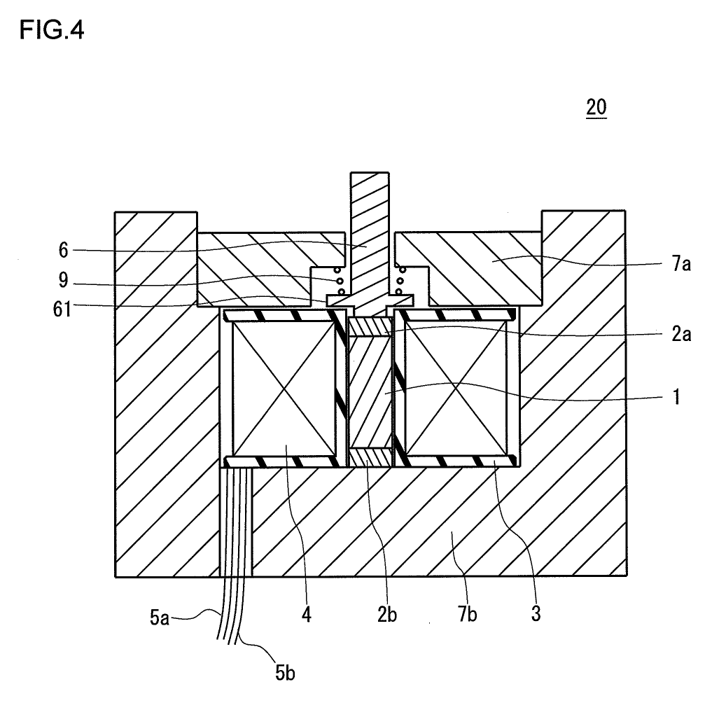

FIG. 4 illustrates an embodiment of the presently disclosed magnetostriction apparatus. Magnetostriction apparatus 20 includes a super magnetostrictor 1, bias magnet 2 (an upper bias magnet 2a and a lower bias magnet 2b), bobbin 3, coil 4, electrical leads 5a and 5b, vibrating rod 6, prestress cap 7a, case 7b and elastic member (helical spring) 9.

The super magnetostrictor 1 is used as a vibration transducer for converting a signal derived from sound into vibration. The super magnetostrictor 1 has a substantially cylindrical shape and is provided with the upper bias magnet 2a on its top and the lower bias magnet 2b on its bottom. The super magnetostrictor 1 is sandwiched between the upper bias magnet 2a and the lower bias magnet 2b and accommodated in the case 7b. The super magnetostrictor 1 is permanently exposed to a bias magnetic field generated by the upper bias magnet 2a and the lower bias magnet 2b (i.e., the bias magnetic field permanently penetrates the super magnetostrictor 1).

Prestress is permanently exerted on the super magnetostrictor 1 by accommodating it in the case 7b, supporting the bottom thereof by the case 7b, and pressing a vibrating rod 6 against the top thereof with the elastic force of the elastic member 9. The super magnetostrictor 1 is subjected to a variable magnetic field generated by the coil 4 disposed around the super magnetostrictor 1, while also being permanently exposed to a bias magnetic field and prestress as described above. As a result, the super magnetostrictor 1 generates vibration in response to an input electric signal.

The coil 4 is formed by wrapping a conductor line around the body of the bobbin 3 as a shaft. The bobbin 3 is made of a material such as glass substrate or polycarbonate. As an electrical signal is input to the conductor line via the electrical lead, the coil 4 generates a magnetic field 4 accordingly. By allowing the variable magnetic field generated by the coil 4 to penetrate the super magnetostrictor 1, the super magnetostrictor 1 expands or contracts in accordance with the intensity of the variable magnetic field, resulting in an output of vibration.

One end of the vibrating rod 6 is mechanically connected to the super magnetostrictor 1 via the upper bias magnet 2a so as to conduct the vibration output from the super magnetostrictor 1 outside by another end. The vibrating rod 61 is provided with a flange part 61. The flange part 61 is urged by the elastic member 9 so as to be pressed against the upper bias magnet 2a. The pressing force is applied to the super magnetostrictor 1 via the upper bias magnet 2a. The flange part 61 and the elastic member 9 prevent the entirety of the vibrating rod 6 from slipping out of the case 7b and the prestress cap 7a.

The case 7b is a container (or a body) which accommodates the super magnetostrictor 1, the upper bias magnet 2a, the lower bias magnet 2b, the bobbin 3, the coil 4, the vibrating rod 6 and the elastic member 9 assembled in a predetermined configuration. The prestress cap 7a is fixed to the case 7a by a spring mechanism, welding, caulking, resin cure or the like. In the process of fixing the prestress cap 7a to the case 7b, prestress is applied to the super magnetostrictor via the elastic member 9. By applying prestress to the super magnetostrictor 1, efficiency of transducing between an electric signal and vibration is improved. The prestress cap 7a and the case 7b are preferably formed of a magnetic material so as not to leak the internal magnetic field outside and to generate the magnetic field inside efficiently.

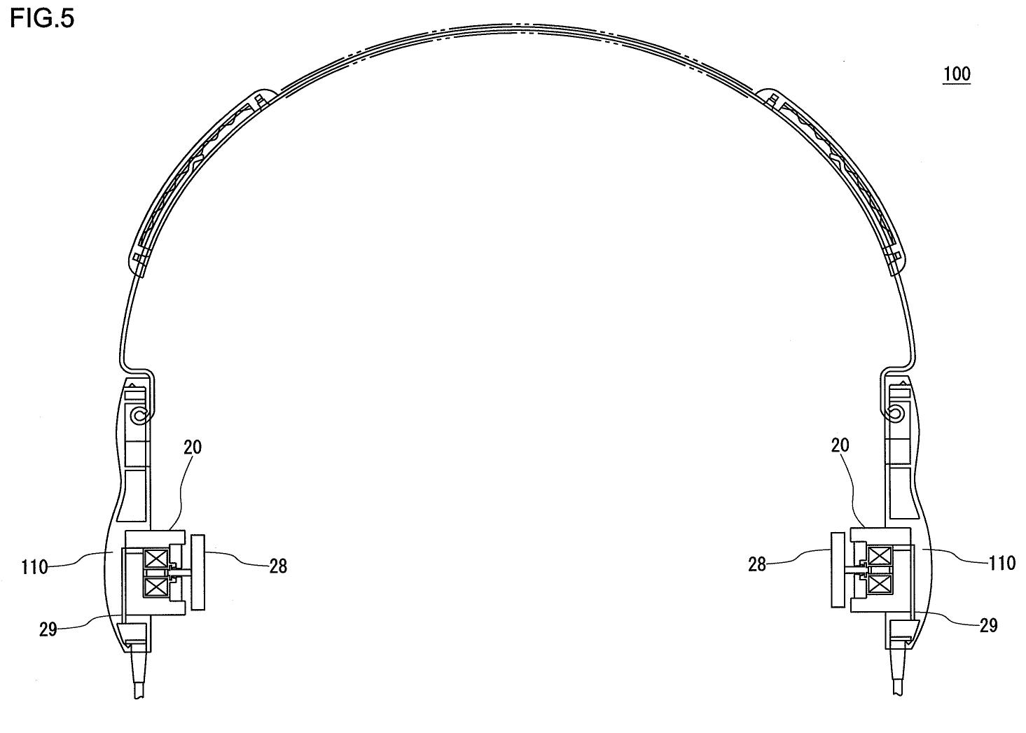

FIG. 5 illustrates a headphone including the magnetostriction apparatus of FIG. 4. The structure of the headphone is an example of an electronic device provided with the magnetostriction apparatus 20 as a vibration generator. A headphone 100 is provided with a main body 110, a magnetostriction apparatus 20, and a vibrating pad 28. The main body 110 includes a circuit 29 for transmitting an electric signal input from a player or similar device outside the appliance to the coil of the magnetostriction apparatus 20. The vibrating pad 28 is fitted to the vibrating rod 6 of the magnetostriction apparatus 20 and conducts the vibration conducted from the vibrating rod 6 to the skull bone in the vicinity of the user's ear. The user can recognize the vibration conducted from the surface of the vibrating pad 28 as sound through bone conduction. A wide tonal range from bass to treble may be reproduced with a high fidelity resulting in excellent acoustic property.

Since the super magnetostrictor 1 is of a cylindrical shape and is displaced in the height direction, it is necessary to connect moving components and the height of the super magnetostrictor 1 in series. To impart necessary vibration to a target object, the super magnetostrictor 1 should have a certain height. Therefore, a constraint is imposed in reducing its size in the height direction. Accordingly, the size and weight of the case 7b and the prestress cap 7a, which occupy a large portion of the total weight of the magnetostriction apparatus 20, need to be reduced. The case 7b should, however, also have a certain inertial mass in order to maintain the low-frequency characteristic.

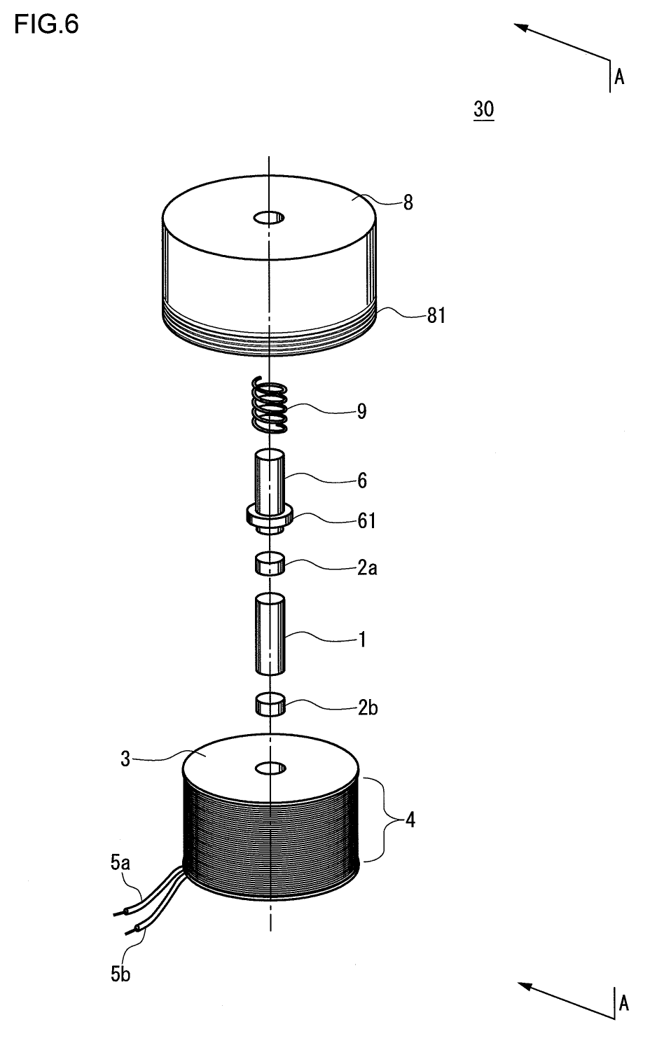

FIG. 6 illustrates a magnetostriction in accordance with an embodiment of the presently disclosed invention. Unlike the magnetostriction apparatus 20 shown in FIG. 4, a magnetostriction apparatus 30 according to the embodiment is provided with a housing 8 in place of the prestress cap 7a and the case 7b. The housing 8 is provided with a screw part 81, which is an example of a connecting mechanism fitting the magnetostriction apparatus 30 to the main body of the electronic device in which the magnetostriction apparatus 30 is provided. The components of the magnetostriction apparatus 30 are accommodated in the housing 8 before being fitted to the main body of the electronic device through the screw part 81. The housing 8 includes a yoke formed of, for example, a soft iron plate in order to adjust a magnetic circuit of a magnetic field generated by the bias magnet 2, the coil 4, and the electrical leads 5a and 5b and to amplify a magnetic field. The bias magnet 2, the coil 4, and the electrical leads 5a and 5b constitute a magnetic field generating means. The yoke creates a closed magnetic path within the housing 8 and prevents a magnetic field from leaking outside.

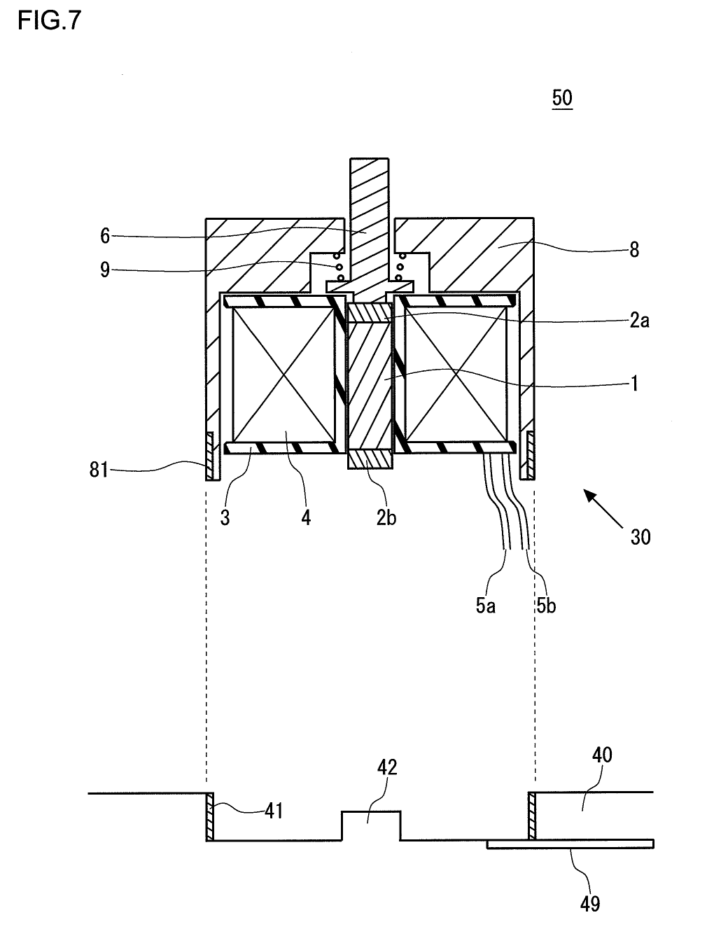

FIG. 7 illustrates an electronic device according to the embodiment disclosed in FIG. 6. A main body 40 of the electronic device 50 is provided with a screw part 41, which is an example of a connecting mechanism for attaching the magnetostriction apparatus 30. By screwing the screw part 81 of the magnetostriction apparatus 30 and the screw part 41 of the main body 40 together, the magnetostriction apparatus 30 is fitted to the main body 40. The connecting mechanism may connect the magnetostriction apparatus 30 to the main body 40 by welding, caulking, resin cure or other means.

The end of the housing 8 facing the main body 40 is open. When the magnetostriction apparatus 30 is fitted to the main body 40, the lower bias magnet 2b comes into direct contact with the main body 40. A projection 42 is provided in a position of the main body 40, which comes into contact with the lower bias magnet 2b. By tightening the screw, the super magnetostrictor 1 is pressed by the projection 42 via the lower bias magnet 2b, applying predetermined prestress to the super magnetostrictor 1. The electrical leads 5a and 5b are connected to a circuit 49 of the main body 40 so that an electrical signal supplied from the circuit 49 is transmitted to the coil 4.

In the magnetostriction apparatus 20 shown in FIG. 4, the case 7b is assigned the function of supporting the fixed end of the super magnetostrictor 1. In the magnetostriction apparatus 30 shown in FIGS. 6 and 7, the main body 40 of the electronic device 50, which includes, for example, a circuit to provide an electric signal to the magnetostriction apparatus 30, is assigned the supporting function. The housing 8 is provided to accommodate components such as the super magnetostrictor 1, the coil 4, the bias magnet 2, and the elastic member 9. The housing 8 is not assigned the function of supporting the fixed end of the super magnetostrictor 1 or the function of applying prestress to the super magnetostrictor 1. This eliminates the need to provide a member with a large inertial mass in the magnetostriction apparatus 30 and allows the prestress cap for applying prestress to the super magnetostrictor 1 to be omitted. Consequently, this reduces the size and weight of the magnetostriction apparatus 30 and, ultimately, of the electronic device 50 as a whole.

Prior art approaches require a built in case and a prestress cap with the magnetostriction apparatus in the likes of an electronic device. In contrast, the magnetostriction apparatus 30 of the embodiment can be fitted to any main body 40 so long as the main body 40 has sufficient mass and hardness. Accordingly, electronic devices using the magnetostriction apparatus 30 can be designed flexibly.

The main body 40 of the electronic device 50 operates to apply prestress to the super magnetostrictor 1 and suppress vibration at the fixed end of the super magnetostrictor 1. This approach obviates the need for the magnetostriction apparatus 30 itself to have an inertial mass sufficient to suppress vibration at the fixed end of the super magnetostrictor 1 and allows significant reduction in size and weight. This approach also permits omission of some of the members for sandwiching the super magnetostrictor 1 from above and below and applying prestress thereto, which successfully resulted in reduction in height. A trade off between maintenance of frequency characteristic and reduction in size and weight is thereby achieved.

As described above, an inertial mass 13.8 times or larger than the moving weight should be provided at the fixed end in order to suppress vibration at the fixed end of the super magnetostrictor and efficiently conduct the vibration at the output end outside. For this purpose, the main body 40 should have mass approximately 13.8 times or larger, 21 times or larger, or (more preferably), 69 times or larger than the total mass of the super magnetostrictor 1, the bias magnet 2, the elastic member 9, and the vibrating rod 6. If an additional part vibrated by the vibrating rod 6 (e.g., a vibrating pad for fitting the headphone close to the ear of the user) is provided, the mass of such a part shall be included in the mass of the vibrating rod 6. The mass of constituent members that can be regarded as being mechanically integral with the main body 40 may be included in the mass of the main body 40.

The member (the projection 42 in the example of FIG. 7) in the main body 40 with which the structure of the fixed end comes into contact desirably has sufficient hardness to suppress vibration at the fixed end of the super magnetostrictor 1. The housing 8 is preferably made of a magnetic material. In case the magnetostriction apparatus 30 is used in a headphone or the like, however, the housing 8 may not be formed of a magnetic material because the magnetic field generated is not so intense. In this case, the housing 8 may be formed of a light material to achieve lightweight.

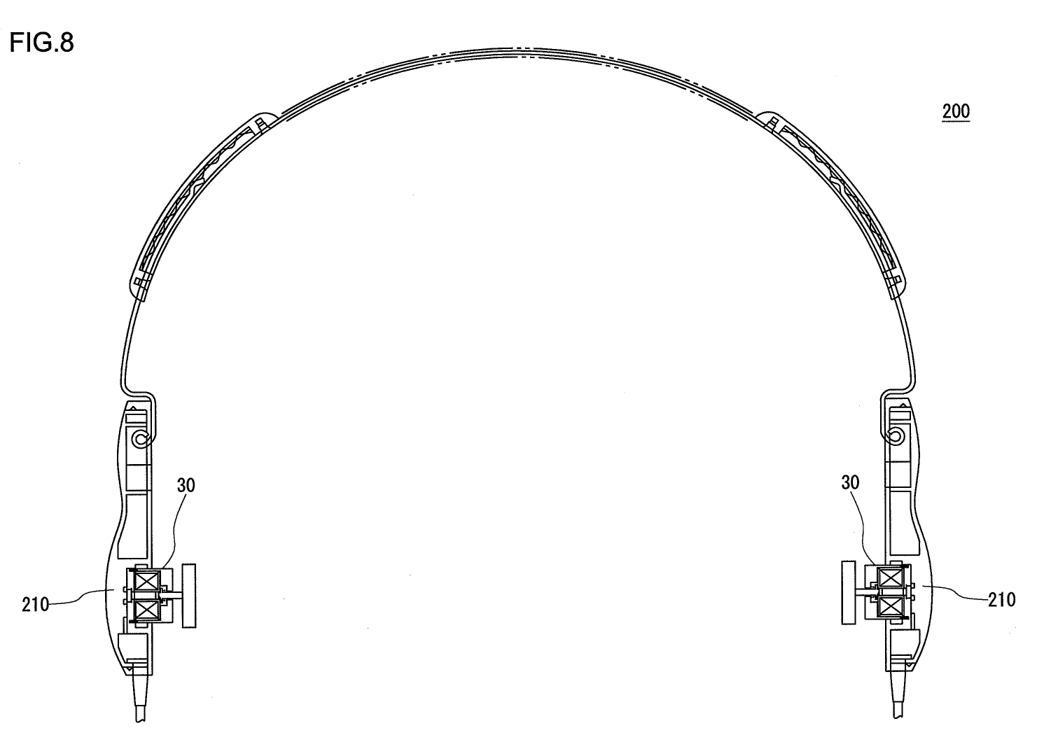

FIG. 8 shows the structure of a headphone as an example of the electronic device 50 provided with the magnetostriction apparatus 30 shown in FIG. 6. A headphone 200 is provided with the magnetostriction apparatus 30 of an open type shown in FIG. 6 instead of the magnetostriction apparatus 20 of a closed type provided in the headphone 100 shown in FIG. 5. Wide tonal range, bass and treble, may be reproduced with a high fidelity as in the headphone 100 shown in FIG. 5 and with an excellent acoustic property.

The ratio between the moving mass and the inertial mass supporting the fixed end is examined in relation to the frequency characteristic of sound output from the headphones, by rating audio perception by the same person being tested wearing the headphones. Since it is difficult to numerically determine the frequency characteristic of sound perceived by humans through bone conduction, a difference in frequency characteristic is checked by audio perception by the person being tested.

An excellent frequency characteristic is obtained by providing at the fixed end an inertial mass 13.8 times or larger or, more preferably, 69 times or larger than the moving mass. This shows that the main body to which the magnetostriction apparatus 30 is attached is required to have the mass. In the case of the moving mass of the magnetostriction apparatus being is 1.3 g, the mass of the main body may be 17.9 g or greater.

A magnetostriction apparatus 30 may be built that weighs 12.8 g and is attached to the body 40 that weighs 27 g (21 times as heavy as the moving mass) and confirmed that the headphone achieves an excellent acoustic characteristic. The headphone 200 is significantly lighter than the headphone 100, while offering excellent acoustic property as the headphone 100. The housing 8 of the prototype is formed of a metal. If the coil is contained in a yoke formed of Permalloy or the like to create a closed magnetic path, the housing 8 may be formed of a light material such as resin. This can further reduce the mass of the magnetostriction apparatus 30 and, ultimately, the mass of the apparatus like a headphone as a whole.

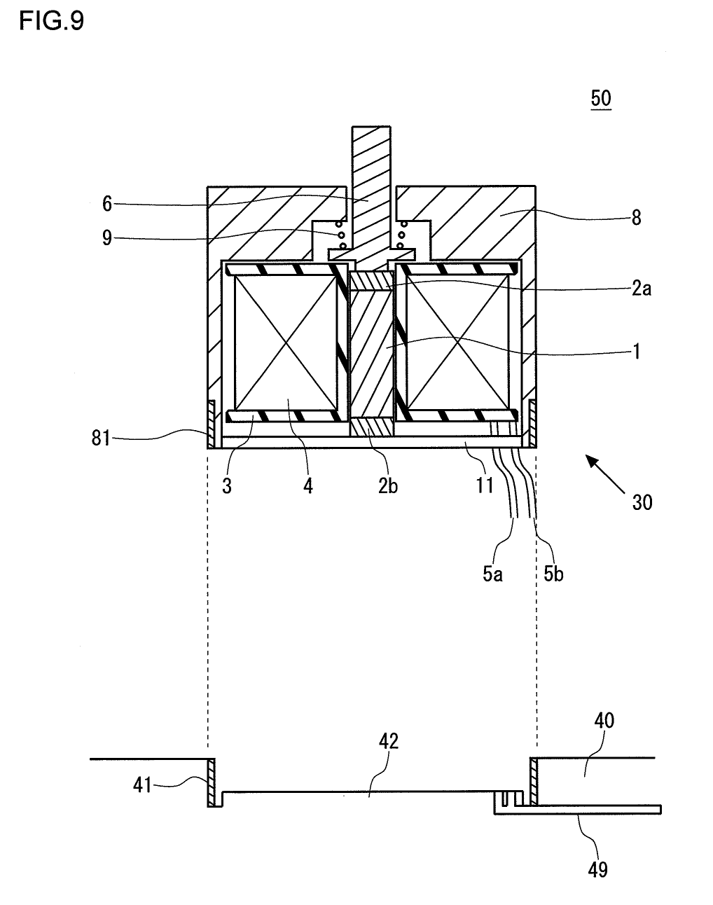

FIG. 9 shows the structure of the electronic device 50 according to a variation of an embodiment of the present invention. The magnetostriction apparatus 30 shown in FIG. 9 is further provided with a bottom plate 11 in addition to the components of the magnetostriction apparatus 30 shown in FIG. 7. The bottom plate 11 may be formed of a plate with waterproof finish for preventing drops of water from invading the magnetostriction apparatus 30 or the main body 40. Alternatively, the bottom plate 11 may be formed of a magnetic material to prevent leakage of magnetic field to the main body 40. Since the magnetostriction apparatus 30 of this variation is provided with the bottom plate 11 facing the main body 40, the apparatus is of a closed type instead of an open type. The bottom plate 11 need not have an inertial mass necessary to suppress vibration at the fixed end of the super magnetostrictor 1. The bottom plate 11 is not provided to suppress vibration at the fixed end of the super magnetostrictor 1. The inertial mass necessary to suppress vibration may be in the main body 40 of the electronic device 50.

In this case, too, the main body 40 should have the weight 16.8 times or larger, 21 times or larger, or preferably 69 times or larger than the moving mass. The mass of the bottom plate 11 may be included in the mass of the main body 40. If there is some member provided between the main body 40 and the super magnetostrictor 1 in addition to the bottom plate 11, the mass of that member may be included in the mass of the main body 40. The fixed end of the super magnetostrictor 1 need be provided with sufficient mass and hardness to suppress vibration at the fixed end. With this, vibration of the super magnetostrictor 1 is efficiently conducted outside. Also, the magnetostriction apparatus 30 may exhibit its excellent frequency characteristic in this way. A particular benefit of the magnetostriction apparatus 30 used in the headphone 200 is that sound quality is improved.

In the embodiment, one super magnetostrictor 1 is provided in the magnetostriction apparatus 30. Alternatively, multiple super magnetostrictors may be provided so long as the main body 40 has enough inertial mass. The size of the super magnetostrictor 1 is as desired.

An electronic device using the magnetostriction apparatus 30 as a vibration generator was described in the embodiment. Alternatively, the magnetostriction apparatus 30 may be used as a vibration detector. In this case, the vibrating rod 6 has the function of conducting vibration applied from outside to the super magnetostrictor 1. The coil 4 functions as a detecting means for detecting variation in magnetic characteristic of the super magnetostrictor 1 in accordance with the vibration applied from outside, in the form of an electrical signal. In this case, too, the housing 8 is provided with a screw part 81 functioning as a connecting means for connecting the apparatus to the main body 40. The hardness and mass of main body 40 is sufficient to suppress vibration at the end of the main body 40 as the super magnetostrictor 1 is vibrated due to the vibration applied from outside. With this, vibration over a wide frequency range can be accurately detected. By eliminating the need to provide the magnetostriction apparatus 30 with a prestress cap or enough inertial mass, the size and weight of the apparatus can be reduced.

The embodiments herein are illustrative in nature and various variations in constituting elements and processes involved are possible. Those skilled in the art would readily appreciate that such variations are also within the scope of the present invention. Arbitrary combinations of the aforementioned constituting elements and implementations of the invention in the form of methods, apparatuses and systems may also be practiced as additional modes of the present invention.

What is claimed is:

1. A magnetostriction apparatus comprising:
a magnetostrictor which expands and contracts in accordance with a magnetic field;
a magnetic field generating means which generates the magnetic field; and
a housing which holds the magnetostrictor and the magnetic field generating means at predetermined positions, wherein the housing is connected to an external member so that a predetermined pressure is applied to the magnetostrictor by the external member and the housing.

2. The magnetostriction apparatus according to claim 1, wherein the external member includes a circuit which supplies a signal for generating the magnetic field to the magnetic field generating means.

3. The magnetostriction apparatus according to claim 1, wherein the housing includes a yoke which adjusts a magnetic circuit of the magnetic field generated by the magnetic field generating means.

4. A magnetostriction apparatus comprising:
a magnetostrictor the magnetic characteristic of which varies in accordance with variation applied from outside;
detecting means which detects variation in the magnetic characteristic in the form an electrical signal;
a housing which holds the magnetostrictor and the detecting means at predetermined positions, wherein the housing is connected to an external member so that a predetermined pressure is applied to the magnetostrictor by the external member and the housing.

5. The magnetostriction apparatus according to claim 4, wherein the external member includes a circuit which acquires the electrical signal from the detecting means.

6. The magnetostriction apparatus according to claim 1, not comprising a structure which supports an end of the magnetostrictor opposite to an end supported by the housing and applies a predetermined pressure to the magnetostrictor.

7. The magnetostriction apparatus according to claim 1, wherein the housing includes a yoke for creating a closed magnetic path within the housing.

8. The magnetostriction apparatus according to claim 1, wherein a face of the housing where the magnetostriction apparatus is connected to the external member is open, and the magnetostriction apparatus is connected to the external member such that the end of the magnetostrictor facing the external member, or a constituting member provided in the magnetostrictor to face the external member comes into contact with the external member.

9. The magnetostriction apparatus according to claim 1, further comprising a vibrating unit which conducts vibration at an end of the magnetostrictor opposite to an end facing the external member, outside the magnetostriction apparatus.
